(19) United States
(12) Patent Application Publication
(10) Pub. No.: US 2025/0006729 A1
(43) Pub. Date: Jan. 2, 2025

(54) RC IGBT and Method of Operating an RC IGBT

(71) Applicant: Infineon Technologies AG, Neubiberg (DE)

(72) Inventors: Roman Baburske, Otterfing (DE); Frank Pfirsch, Munchen (DE)

(21) Appl. No.: 18/754,430

(22) Filed: Jun. 26, 2024

(30) Foreign Application Priority Data
Jun. 27, 2023 (DE) 102023206028.0

(51) Int. Cl. H01L 27/07; H01L 29/739; H01L 29/861

(52) U.S. Cl. CPC H01L 27/0761; H01L 29/7397; H01L 29/861

(57) ABSTRACT

An RC IGBT includes, in a single chip, an active region configured to conduct both a forward load current and a reverse load current between a first load terminal at a front side of a semiconductor body of the RC IGBT and a second load terminal at a back side of the semiconductor body. The active region is separated into at least: an IGBT-only region, at least 90% of which is configured to conduct, based on a first control signal, only the forward load current; an RC IGBT region, at least 90% of which is configured to conduct the reverse load current and, based on a second control signal, the forward load current; and a hybrid region, at least 90% of which is configured to conduct, based on both the first control signal and the second control signal, the forward load current.

### TECHNICAL FIELD

This specification refers to embodiments of an RC IGBT and to embodiments of operating an RC IGBT.

### BACKGROUND

Many functions of modern devices in automotive, consumer and industrial applications, such as converting electrical energy and driving an electric motor or an electric machine, rely on power semiconductor devices. For example, Insulated Gate Bipolar Transistors (IGBTs), Metal Oxide Semiconductor Field Effect Transistors (MOSFETs) and diodes, to name a few, have been used for various applications including, but not limited to switches in power supplies and power converters.

A power semiconductor device usually comprises a semiconductor body configured to conduct a forward load current along a load current path between two load terminals of the device. The load current is typically conducted by means of an active region of the power semiconductor device. The active region is typically surrounded by an edge termination region, which is terminated by an edge of the chip.

In case of a controllable power semiconductor device, e.g., a transistor, the load current path may be controlled by means of an insulated electrode, commonly referred to as gate electrode. For example, upon receiving a corresponding control signal, e.g., from a driver unit via a control terminal of the device, the control electrode may set the power semiconductor device in one of a forward conducting state and a forward blocking state.

Furthermore, some devices provide for reverse load current capability. There, the active region of the semiconductor body is further configured to conduct a reverse load current along a reverse load current path between the two load terminals of the device.

For example, the RC (Reverse Current) IGBT is one representative of such devices. In an RC IGBT, a single chip accommodates an IGBT structure and a diode structure, wherein not only the IGBT, i.e., the forward load current, may be controlled based on said gate signal, but wherein also the characteristic of the diode behavior, i.e., the reverse load current, may be influenced. The present specification relates to such an RC IGBT.

In comparison to a diode and an IGBT on separate chips that are connected anti-parallel to each other, the RC IGBT exhibits some advantages, e.g., in terms turn-on losses, reverse recovery losses and/or thermal behavior, but may also be more complex in control.

### SUMMARY

The subject-matter of the independent claims is presented. Features of exemplary embodiments are defined in the dependent claims.

According to a first embodiment, an RC IGBT comprises, in a single chip, an active region configured to conduct both a forward load current and a reverse load current between a first load terminal at a front side of a semiconductor body of the RC IGBT and a second load terminal at a back side of the semiconductor body. The active region is separated into at least: an IGBT-only region, at least 90% of which being configured to conduct, based on a first control signal, only the forward load current; an RC IGBT region, at least 90% of which being configured to conduct the reverse load current and, based on a second control signal, the forward load current; and a hybrid region, at least 90% of which being configured to conduct, based on both the first control signal and the second control signal, the forward load current.

According to a further embodiment, a method of operating an RC IGBT according to the first embodiment is presented. The method comprises controlling the RC IGBT based on the first control signal and the second control signal.

Those skilled in the art will recognize additional features and advantages upon reading the following detailed description, and upon viewing the accompanying drawings.

### BRIEF DESCRIPTION OF THE DRAWINGS

The parts in the figures are not necessarily to scale, instead emphasis is being placed upon illustrating principles of the invention. Moreover, in the figures, like reference numerals designate corresponding parts. In the drawings:

FIG. 1 schematically and exemplarily illustrates a section of a horizontal projection of an RC IGBT in accordance with one or more embodiments;

FIG. 2 schematically and exemplarily illustrates a section of a horizontal projection of an active region of an RC IGBT in accordance with one or more embodiments;

FIG. 3 schematically and exemplarily illustrates a section of a vertical cross-section of an RC IGBT in accordance with one or more embodiments;

FIG. 4 schematically and exemplarily illustrates a method of operating an RC IGBT in accordance with one or more embodiments; and

FIG. 5 schematically and exemplarily illustrates theoretical standalone output characteristics of an RC IGBT region and a hybrid region of an RC IGBT in accordance with one or more embodiments;

FIG. 6 schematically and exemplarily illustrates a section of a vertical cross-section of an RC IGBT in accordance with one or more embodiments; and

FIG. 7 schematically and exemplarily illustrates a section of a vertical cross-section of an RC IGBT in accordance with one or more embodiments.

### DETAILED DESCRIPTION

In the following detailed description, reference is made to the accompanying drawings which form a part hereof and in which are shown by way of illustration specific embodiments in which the invention may be practiced.

In this regard, directional terminology, such as “top”, “bottom”, “below”, “front”, “behind”, “back”, “leading”, “trailing”, “above” etc., may be used with reference to the orientation of the figures being described. Because parts of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

Reference will now be made in detail to various embodiments, one or more examples of which are illustrated in the figures. Each example is provided by way of explanation, and is not meant as a limitation of the invention. For example, features illustrated or described as part of one embodiment can be used on or in conjunction with other embodiments to yield yet a further embodiment. It is intended that the present invention includes such modifications and variations. The examples are described using specific language which should not be construed as limiting the scope of the appended claims. The drawings are not scaled and are for illustrative purposes only. For clarity, the same elements or manufacturing steps have been designated by the same references in the different drawings if not stated otherwise.

The term “horizontal” as used in this specification intends to describe an orientation substantially parallel to a horizontal surface of a semiconductor substrate or of a semiconductor structure. This can be for instance the surface of a semiconductor wafer or a die or a chip. For example, both the first lateral direction X and the second lateral direction Y mentioned below can be horizontal directions, wherein the first lateral direction X and the second lateral direction Y may be perpendicular to each other.

The term “vertical” as used in this specification intends to describe an orientation which is substantially arranged perpendicular to the horizontal surface, i.e., parallel to the normal direction of the surface of the semiconductor wafer/chip/die. For example, the extension direction Z mentioned below may be an extension direction that is perpendicular to both the first lateral direction X and the second lateral direction Y. The extension direction Z is also referred to as “vertical direction Z” herein.

In this specification, n-doped is referred to as “first conductivity type” while p-doped is referred to as “second conductivity type”. Alternatively, opposite doping relations can be employed so that the first conductivity type can be p-doped and the second conductivity type can be n-doped.

In the context of the present specification, the terms “in ohmic contact”, “in electric contact”, “in ohmic connection”, and “electrically connected” intend to describe that there is a low ohmic electric connection or low ohmic current path between two regions, sections, zones, portions or parts of a semiconductor device or between different terminals of one or more devices or between a terminal or a metallization or an electrode and a portion or part of a semiconductor device, wherein “low ohmic” may mean that the characteristics of the respective contact are essentially not influenced by the ohmic resistance. Further, in the context of the present specification, the term “in contact” intends to describe that there is a direct physical connection between two elements of the respective semiconductor device; e.g., a transition between two elements being in contact with each other may not include a further intermediate element or the like.

In addition, in the context of the present specification, the term “electric insulation” is used, if not stated otherwise, in the context of its general valid understanding and thus intends to describe that two or more components are positioned separately from each other and that there is no ohmic connection connecting those components. However, components being electrically insulated from each other may nevertheless be coupled to each other, for example mechanically coupled and/or capacitively coupled and/or inductively coupled and/or electrostatically coupled (for example, in case of a junction). To give an example, two electrodes of a capacitor may be electrically insulated from each other and, at the same time, mechanically and capacitively coupled to each other, e.g., by means of an insulation, e.g., a dielectric.

Specific embodiments described in this specification pertain to, without being limited thereto, an RC IGBT, e.g., a power semiconductor device that may be used within a power converter or a power supply. Thus, in an embodiment, such RC IGBT can be configured to carry a load current that is to be fed to a load and/or, respectively, that is provided by a power source. For example, the RC IGBT may comprise one or more active power semiconductor unit cells, such as a monolithically integrated diode cell, a derivative of a monolithically integrated diode cell, a monolithically integrated transistor cell, e.g., a monolithically integrated IGBT cell and/or derivatives thereof. Such diode/transistor cells may be integrated in a power semiconductor module. A plurality of such cells may constitute a cell field that is arranged within an active region of the power semiconductor device.

The term “blocking state” of the RC IGBT may refer to conditions, when the RC IGBT is in a state configured for blocking a load current flow while an external voltage is applied. More particularly, the RC IGBT may be configured for blocking a forward load current through the RC IGBT while a forward voltage bias is applied. In comparison, the RC IGBT may be configured for conducting the forward load current in a “conducting state” of the RC IGBT while a forward voltage bias is applied. A transition between the blocking state and the conducting state may be controlled by a control electrode or, more particularly, a potential of the control electrode. Said electrical characteristics may, of course, only apply within a predetermined working range of the external voltage and the current density within the RC IGBT. The term “forward biased blocking state” therefore may refer to conditions with the RC IGBT being in the blocking state while a forward voltage bias is applied.

The term “RC IGBT” as used in this specification intends to describe an RC IGBT on a single chip with high voltage blocking and/or high current-carrying capabilities. In other words, such RC IGBT is intended for high current, typically in the Ampere range, e.g., up to several ten or hundred Ampere, and/or high voltages, typically above 100 V, more typically 400 V and above, e.g., up to at least 1200 V or even more, e.g., up to at least 3 kV, or even up to 10 kV or more, depending on the respective application.

For example, the term “RC IGBT” as used in this specification is not directed to logic semiconductor devices that are used for, e.g., storing data, computing data and/or other types of semiconductor-based data processing.

For example, the RC IGBT described below may be a single semiconductor chip, e.g., exhibiting a stripe cell configuration (or a cellular/needle cell configuration) and can be configured to be employed as a power component in a low-, medium- and/or high voltage application.

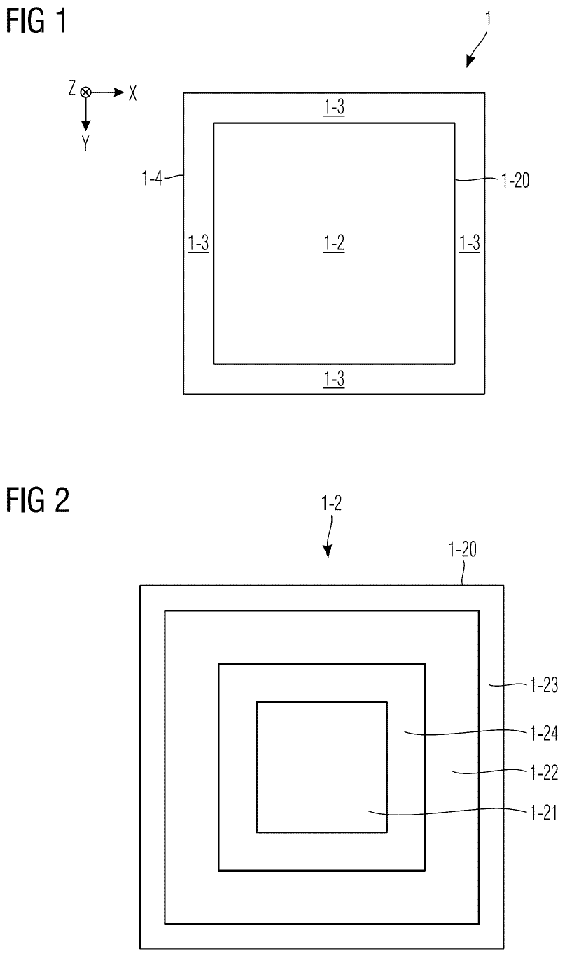

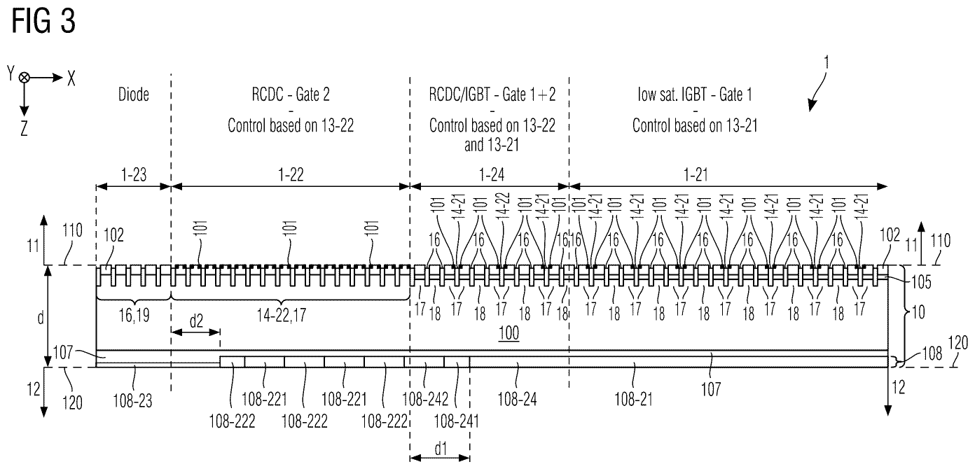

FIG. 1 schematically and exemplarily illustrates a section of a horizontal projection of a RC IGBT 1 in accordance with one or more embodiments. The vertical cross-section illustrated in FIG. 3 as well as the more detailed illustration of an exemplary active region 1-2 according to FIG. 2 are additionally referred to in the following.

The RC IGBT 1 comprises a semiconductor body 10 coupled to a first load terminal at a front side (also referred to as first side) 110 and to a second load terminal 12 at a back side (also referred to as back side) 120 that is opposite to the front side 110 with respect to the vertical direction Z. The semiconductor body 10 is part of a single chip that comprises an active region 1-2 configured to conduct both a forward load current and a reverse load current between the first load terminal 11 and the second load terminal 12 at the back side 120.

The vertical thickness d of the semiconductor body 10 may be defined as the distance between the front side 110 and the back side 120 along the vertical direction Z, e.g., measured at a horizontal center of the active region 1-2.

The RC IGBT 1 may exhibit a vertical configuration according to which the both the forward load current and the reverse load current flow substantially in parallel to the vertical direction Z.

For example, the first load terminal 11 may be a source (or emitter) terminal, and the second load terminal 12 a drain (collector) terminal.

The active region 1-1 is surrounded by an edge termination region 1-3 which is terminated by a chip edge 1-4. Herein, the terms “active region” (sometimes also referred to as “cell field”), “edge termination region” and “chip edge” have the technical meanings the skilled person typically associates therewith in the context of RC IGBTs and are hence not explained in further detail.

According to the embodiments disclosed herein, the active region 1-2 of the RC IGBT 1 is separated into at least an IGBT-only region 1-21, an RC IGBT region 1-22, and a hybrid region 1-24.

For example, at least 90% of the IGBT-only region 1-21 is configured to conduct, based on a first control signal 13-21, only the forward load current. Said share of at least 90% can be even greater than 90%, e.g., at least 95%, at least 98% or even amount to 100%. In other words, the IGBT-only region 1-21 is configured not to contribute to the reverse load current carrying capability.

For example, at least 90% of the RC IGBT region 1-22 is configured to conduct the reverse load current and, for example based on only a second control signal 13-22, the forward load current. Said share of at least 90% can be even greater than 90%, e.g., at least 95%, at least 98% or even amount to 100%. The RC IGBT region 1-22 is in an embodiment configured to not control the forward load current based on the first control signal 13-21 but to control the forward load current based only on the second control signal 13-22. For example, at least 90% or at least 95% or at least 98% or even 100% of the RC IGBT region 1-22 may be devoid of control trench electrodes connected to the first control signal 13-21.

For example, at least 90% of the hybrid region 1-24 is configured to conduct, based on both the first control signal 13-21 and the second control signal 13-22, the forward load current. Said share of at least 90% can be even greater than 90%, e.g., at least 95%, at least 98% or even amount to 100%. For example, the hybrid region 1-24 exhibits an RC IGBT configuration or an IGBT configuration.

In accordance with one or more embodiments, the hybrid region 1-24 is configured to conduct the forward load current both during the forward conduction phase and the forward desaturation phase of the RC IGBT 1. This may yield to a performance increase, e.g., to an improvement of the over-current turn-off robustness, as the current during turn-off is not only carried by the RC IGBT region 1-22, but is distributed within both the RC IGBT region 1-22 and the hybrid region 1-24. This can result in a reduced current density at turn-off.

In addition, the active region 1-2 may comprise a diode-only region 1-23, which will be explained in more detail below.

It shall be understood that the arrangement of the IGBT-only region 1-21, the RC IGBT region 1-22, the hybrid region 1-24 and the optional diode-only region 1-23 as illustrated in FIG. 2 is only exemplary. For example, said regions 1-21, 1-22, 1-24 and 1-23 need not necessarily be contiguous regions but could also be constituted by spatially distributed subregions. Also, instead of being centrally arranged, the IGBT-only region 1-21 could alternatively or additionally be arranged in periphery portions of the active region 1-2. For example, said regions 1-21, 1-22, 1-24 and (optionally) 1-23 may exhibit a rectangular lateral circumference and arranged in accordance with a stripe pattern in the active region 1-2. The latter variant could facilitate providing of the control signals to the regions 1-21, 1-22 and 1-24.

The skilled person may dimension and arrange said three regions 1-21, 1-22 and 1-23 within the active region 1-2 according to the designated characteristics of the RC IGBT 1 and further circumstances.

In an embodiment, the second control signal 13-22 is different from the first control signal 13-21. For example, the second control signal 13-22 is generated separately from the first control signal 13-21. Thereby, the control of the forward load current in the IGBT-only region 1-21 can be independent of the control of the forward load current in the RC IGBT region 1-22. In the hybrid region 1-24, however, the forward load current is controlled based on both the first control signal 13-21 and the second control signal 13-22.

In an embodiment, the active region 1-2 is separated into at least a) the distinct IGBT-only region 1-21 that only carries the forward load current (and not the reverse load current) and that is controlled based on the first control signal 13-21; b) the distinct RC IGBT region 1-22 that carries both the forward load current and the reverse load current and that is controlled based on the second control signal 13-22 that may be independent of the first control signal 13-21; and c) the hybrid region 1-24, which may either exhibit an IGBT configuration or an RC IGBT configuration and which is controlled based on both the first control signal 13-21 and the second control signal 13-22.

In an embodiment, the RC IGBT region 1-22 is configured to conduct the reverse load current irrespective of the second control signal 13-22.

The IGBT-only region 1-21 and the RC IGBT region 1-22 may occupy the major portion of the active region 1-2; e.g., the IGBT-only region 1-21 and the RC IGBT region 1-22 amount to at least 80% of the active region 1-2. A remaining portion of the active region 1-2 may, for example, be occupied by the hybrid region 1-24 and the optional diode-only region 1-23. For example, up to 70% of the active region 1-2 may be occupied by the IGBT-only region 1-21, up to 25% of the active region 1-2 may be occupied by the RC-IGBT region 1-22, and up to 10% of the active region 1-2 may be occupied by the hybrid region 1-23. But, theses numbers or just exemplary, and, as indicated above, the skilled person may dimension said three regions 1-21, 1-22 and 1-23 according to the designated characteristics of the RC IGBT 1 and further circumstances.

Each of the IGBT-only region 1-21, the RC IGBT region 1-22 and the hybrid region 1-24 may exhibit a total lateral extension of at least 20% of the vertical thickness d of the semiconductor body 10. One or more of said total lateral extensions may even be greater, such as at least 70%, 80% or even more than 100% of the vertical thickness d of the semiconductor body 10. For example, the IGBT-only region 1-21 is the largest of said three regions 1-21, 1-22 and 1-24 and has a total lateral extension of at least 100% of the vertical thickness d of the semiconductor body 10. For example, the RC IGBT region 1-22 is the second largest of said three regions 1-21, 1-22 and 1-24 and has a total lateral extension of at least 70% of the vertical thickness d of the semiconductor body 10. For example, the hybrid region 1-24 is the smallest of said three regions 1-21, 1-22 and 1-24 and has a total lateral extension of at least 20% of the vertical thickness d of the semiconductor body 10. If provided, the diode-only region 1-23 is smaller than each of said three regions 1-21, 1-22 and 1-24 and has a total lateral extension of at least 10% of the vertical thickness d of the semiconductor body 10. However, said lateral extensions may be smaller (relative to the vertical thickness d of the semiconductor body 10) in case the RC IGBT 1 is configured for very high blocking voltages and accordingly exhibits a correspondingly great vertical thickness d of the semiconductor body 10.

In an embodiment, the IGBT-only region 1-21, the RC IGBT region 1-22 and the hybrid region 1-24 are spatially separated from each other. For example, there is no spatial overlap between said regions.

Further, the IGBT-only region 1-21 can be a first contiguous region, the RC IGBT region 1-22 can a second contiguous region, and the hybrid region 1-24 can be a third contiguous region, wherein said three contiguous regions can be arranged separately from each other.

For example, at least 90% of the optional diode-only region 1-23 is configured to conduct only the reverse load current (but, e.g., not the forward load current). In an embodiment, the diode-only region 1-23 is not subjected to the first control signal 13-21 or the second control signal 13-22. For example, the diode-only region 1-23 does not comprise any control trench. Furthermore, it may be provided that the diode-only region 1-23 does not comprise any semiconductor source region 101 electrically connected to the first load terminal 11.

As indicated above, the skilled person may dimension and arrange said three regions 1-21, 1-22 and 1-24 (and the optional diode-only region 1-23) within the active region 1-2 according to the designated characteristics of the RC IGBT 1. Furthermore, the formulation “at least 90%” used within the context of describing these regions shall express that the primary purpose of the regions is conduct either the forward load current only (in case of the IGBT-only region 1-21), or the reverse load current only (in case of the optional diode-only region 1-23), or both the forward load current and the reverse load current (in case of the RC IGBT region 1-22). The same applies to the hybrid region 1-24, which may for example exhibit an IGBT configuration (forward load current only) or an RC IGBT configuration (both the forward load current and the reverse load current).

In an embodiment, the characteristics of said regions may deviate in respective smaller subportions of 10% or less of said regions, e.g., in a transition region where one of the regions 1-21, 1-22, 1-23 and 1-24 adjoins another one of these regions. Such transitions will be described further below in more detail.

Reference will now be made in more detail to FIG. 3, which illustrates a section of a vertical cross-section of an exemplary embodiment of the active region 1-2, which includes the IGBT-only region 1-21, the RC IGBT region 1-22, the hybrid region 1-24 and the diode-only region 1-23. It is again emphasized that the diode-only region 1-23 is optional. In other embodiments where no diode-only region 1-23 is provided, the reverse load current is entirely carried by the RC IGBT region 1-22.

As illustrated, the active region 1-2 exhibits a vertical configuration with the first load terminal 11 being arranged at the semiconductor body front side 110 and the second load terminal 12 being arranged at the semiconductor body back side 120. The first load terminal 11 and the second load terminal 12 may be shared by each of the IGBT-only region 1-21, the RC IGBT region 1-22, the hybrid region 1-24 and the diode-only region 1-23.

A drift region 100 of the first conductivity type may form the major central portion of the semiconductor body 10 with respect to the vertical direction Z. This drift region 100 may be shared by each of the IGBT-only region 1-21, the RC IGBT region 1-22, the hybrid region 1-24 and (if present) by the diode-only region 1-23.

The active region 1-2 may be configured, both at the front side 110 and at the back side 120, according to the distribution of the IGBT-only region 1-21, the RC IGBT region 1-22, the hybrid region 1-24 and the diode-only region 1-23.

For example, regarding the back side 120, in electrical connection with the second load terminal 12, there is a arranged a back side emitter 108 coupled to the drift region 100, wherein the back side emitter 108 is configured in accordance with the separation of the active region 1-2 into at least the IGBT-only region 1-21, the RC IGBT region 1-22, the hybrid region 1-24 and, if implemented, the diode-only region 1-23.

In an embodiment, the back side emitter 108 may be configured with:
a first section 108-21 of the second conductivity type in a portion of the active region 1-2 where the IGBT-only region 1-21 is present;
a second section 108-22 including both first subsections 108-221 of the first conductivity type and second subsections 108-222 of the second conductivity type in a portion of the active region 1-2 where the RC IGBT region 1-22 is present;
a fourth section 108-24 in a portion of the active region 1-2 where the hybrid region 1-24 is present, wherein the fourth section 108-24 is, in terms of conductivity type, configured in accordance with at least one of the first section 108-21 and the second section 108-22;
and, optionally, if the diode-only region 1-23 is implemented, with a third section 108-23 of the first conductivity type in a portion of the active region 1-2 where the diode-only region 1-23 is present.

For example, the first section 108-21 of the back side emitter 108 is of only the second conductivity type. That is, in an embodiment, the first section 108-21 does not comprise any portions of the first conductivity type.

Furthermore, the first section 108-21 of the back side emitter 108 may exhibit, with respect to its total lateral extension along the first lateral direction X and at a certain vertical level, an average dopant concentration of at least 2*10¹⁵ cm⁻³. Said average dopant concentration can be even greater, e.g., amount to at least 2*10¹⁶ cm⁻³ or 1*10¹⁷ cm⁻³.

This said, in an embodiment, the first section 108-21 of the back side emitter 108 may exhibit, at a certain vertical level and along at least one of the first lateral direction X and the second lateral direction Y, a variation of the dopant concentration. For example, based on the VLD (variation of the lateral dopant concentration), certain characteristics, e.g., the emitter efficiency, of the of backside emitter 108 may be adjusted in the IGBT-only region 1-21. This may allow homogenizing a temperature profile within the semiconductor body 10. In an example, in a subsection of the first section 108-21 in the neighborhood of 1-24, the dopant concentration amounts to less than 80% of the dopant concentration in the center of the first section 108-21. This design may allow suppressing a diagonal current flow from the front side of hybrid region 1-24 towards the first section 108-21 during a desaturation phase. In accordance with an embodiment, in all p doped sections of the back side emitter 108, there is included a pattern of p⁺⁺ stripes and p stripes with a respective stripe width smaller than 30% of the thickness d of the semiconductor body 10. The ratio between the dopant concentration of the p⁺⁺ stripes and the dopant concentration of the p-stripes ma amount to at least two, or to at least five or to at least ten.

Further, the first section 108-21 can be displaced from the RC IGBT region 1-22, e.g., at least by the hybrid region 1-24. In other words, the hybrid region 1-24 may be arranged between the IGBT-only region 1-21 and the RC IGBT region 1-22.

Now regarding the second section 108-22 of the back side emitter 108, in an embodiment, each of the first subsections 108-221 of the second section 108-22 of the back side emitter 108 exhibits, with respect to its respective total lateral extension along the first lateral direction X and at a certain vertical level, an average dopant concentration of at least 1*10¹⁸ cm⁻³. Said average dopant concentration can be even greater, e.g., amount to at least 5*10¹⁸ cm⁻³ or 1*10¹⁹ cm⁻³.

Further, each of the second subsections 108-222 can be displaced from the diode-only region 1-23 by a second distance d2 of at least 20% of the thickness d of the semiconductor body 10. For example, based on the second distance d2, it may be ensured that there is no or only limited injection of holes out of the second subsections 108-222 during the diode reverse recovery process. In an embodiment, the third section 108-23 of the back side emitter 108 may include one or more p-doped regions to provoke an injection of holes during the diode reverse-recovery phase.

The third section 108-23 of the back side emitter region 108 can be a region of only the first conductivity type. In another embodiment, the third section 108-23 may include (non-illustrated) subsections of the second conductivity type that are also electrically connected to the second load terminal, e.g., “p-shorts” similar to the “n-shorts”/first subsections 108-221 of the first conductivity type in the second section 108-22 of the back side emitter 108.

As explained above, the hybrid region 1-24 can exhibit either an IGBT configuration or an RC IGBT configuration. Accordingly, the fourth section 108-24 of the back side emitter 108 can either be configured similar to the first section 108-21 (i.e., IGBT configuration) or similar to the second section 108-22 (i.e., RC IGBT configuration).

In an embodiment, as illustrated, in a portion of the fourth section 108-24 adjacent to the IGBT-only region 1-21, the fourth section 108-24 can be of (only) the second conductivity type. That is, in an embodiment, in said portion, the fourth section 108-24 does not comprise any regions of the first conductivity type. Furthermore, in said portion, the fourth section 108-24 of the back side emitter 108 may exhibit, with respect to its total lateral extension along the first lateral direction X and at a certain vertical level, an average dopant concentration of at least 2*10¹⁵ cm⁻³. Said average dopant concentration can be even greater, greater, e.g., amount to at least 2*10¹⁶ cm⁻³ or 1*10¹⁷ cm⁻³. Also, as the first section 108-21, in an embodiment, in said portion, the fourth section 108-24 of the back side emitter 108 may exhibit, at a certain vertical level and along at least one of the first lateral direction X and the second lateral direction Y, a variation of the dopant concentration. For example, based on the VLD (variation of the lateral dopant concentration), certain characteristics, such as the emitter efficiency, of the of backside emitter 108 may be adjusted in the IGBT-only region 1-21, as has been explained above.

On the other hand, in an embodiment and as illustrated, in a portion of the fourth section 108-24 adjacent to the RC-IGBT region 1-22, the fourth section 108-24 can be configured as the second section 108-22. In said portion, the fourth section 108-24 can include both first subsections 108-241 of the first conductivity type and second subsections 108-242 of the second conductivity type. The above exemplarily provided description of the first subsections 108-221 and second subsections 108-222 of the second section 108-2 may equally apply to the first subsections 108-241 and second subsections 108-242 of the fourth section 108-24. Even the first section 108-21 may exhibit first subsections (not illustrated) close to the transition towards the hybrid region 1-24. Such non-illustrated subsections may have a lateral extension amounting to the thickness d of the semiconductor body 10, or even up to twice the thickness d.

In a further embodiment, the RC IGBT 1 further comprises a field stop region 107 of the first conductivity type arranged in contact with both the drift region 100 and with each of the first section 108-21, the second section 108-22, the fourth section 108-24 and, if implemented, the third section 108-23 of the back side emitter 108. The dopant concentration of the field stop region 107 can be greater than the dopant concentration of the drift region 100.

As illustrated, the thicknesses of the first section 108-21, the second section 108-22, the fourth section 108-24 and, if implemented, the third section 108-23 of the back side emitter 108 may vary. For example, the third section 108-23 of the back side emitter 108 in the optional diode-only region 1-23 may be thinner than the remaining sections 108-21, 108-22 and 108-24 of the back side emitter 108. A lower thickness of the back side emitter 108 may reduce its emitter efficiency, which may allow lower switching losses (e.g., diode reverse recovery losses). Where the back side emitter 108 is reduced in thickness, the field stop region 107 may be thicker as compared to its remaining portion laterally overlapping with the sections 108-21, 108-22 and 108-24 of the back side emitter 108. Said configuration of the back side emitter 108 and the field stop layer 107 in the optional diode-only region 1-23 may extend into the RC IGBT region 1-22 along a path corresponding to the distance d2, as illustrated.

As indicated above, the configuration of the active region 1-2 may also at the front side 110 reflect the active region's 1-2 separation into the at least the IGBT-only region 1-21, the RC IGBT region 1-22, the hybrid region 1-24 and, if implemented, the diode-only region 1-23.

For example, the RC IGBT 1 further comprises, at the front side 110, a trench-mesa-pattern, wherein the trench-mesa-pattern is configured in accordance with the separation of the active region 1-2 into at least the IGBT-only region 1-21, the RC IGBT region 1-22, the hybrid region 1-24 and, if implemented, the diode-only region 1-23. This will be described in more detail below:

An exemplary configuration of the trench-mesa-pattern at the front side 110 is illustrated in FIG. 3. The illustrated trench-mesa-pattern comprises first control trenches 14-21 configured to receive the first control signal 13-21 and second control trenches 14-22 configured to receive the second control signal 13-22. In terms of structure, the first control trenches 14-21 and the second control trenches 14-22 may be equally configured.

For example, the IGBT-only region 1-21 comprises a plurality of the first control trenches 14-21, but, optionally, none of the second control trenches 14-22. That is, in an embodiment, the IGBT-only region 1-21 is controlled solely based on the first control trenches 14-21, as none of the second control trenches 14-22 is present in the IGBT-only region 1-21.

Further, the RC-IGBT region 1-22 may comprises a plurality of the second control trenches 14-22), but, optionally, none of the first control trenches 14-21. That is, in an embodiment, the RC IGBT region 1-22 is controlled solely based on the second control trenches 14-22, as none of the first control trenches 14-21 is present in the RC IGBT region 1-22.

Further, the hybrid region 1-24 may comprise both a plurality of the first control trenches 14-21 and a plurality of the second control trenches 14-22. Accordingly, the hybrid region 1-22 may be controlled based on both the first control trenches 14-21 (that receive the first control signal 13-21) and the second control trenches 14-22 (that receive the second control signal 13-22). By contrast, as explained above, in an embodiment, the RC IGBT region 1-22 does not comprise any first control trench 14-21, and the IGBT-only region 1-21 does not comprise any second control trench 14-22.

In an embodiment, the trench-mesa-pattern may further comprise source trenches 16 electrically connected to the first load terminal 11 and arranged at least in the IGBT-only region 1-21, the hybrid region 1-24 and, if implemented, optionally also in the diode-only region 1-23. For example, the RC IGBT region 1-22 does not comprise any source trench 16.

For example, the diode-only region 1-23 comprises only source trenches 16, but no control trenches. In the RC IGBT region 1-22, there may be only second control trenches 14-22, but no source trenches 16 and no first trenches 14-21. In the hybrid region 1-24, there may for example be arranged two source trenches 16 between respective two adjacent control trenches 14-21/14-22. For example, the first and second control trenches 14-21/14-22 may be arranged in an alternating manner along the first lateral direction X, and between each pair of control trenches 14-21/14-22, there is/are arranged one or more source trenches 16. In the IGBT-only region 1-21, there may for example be arranged one, two or more source trenches 16 between respective two adjacent first control trenches 14-21.

In an embodiment, the trench-mesa-pattern further comprises first type mesas 17 arranged in each of the IGBT-only region 1-21, the RC IGBT region 1-22 and the hybrid region 1-24. Each first type mesa 17 includes a source region 101 of the first conductivity type and a body region 102 of the second conductivity type. For the sake of a clear representation, only a few of the source regions 101 present in the RC IGBT region 1-22 are provided with a respective reference sign. Each bold little square represents a source region 101. Furthermore, each illustrated trench in the RC IGBT region 1-22 represents a second control trench 14-22, wherein the second control trenches 14-22 laterally confine the first type mesas 17 in the RC IGBT region 1-22.

Regarding each of the RC IGBT region 1-22, the hybrid region 1-24 and the IGBT-only region 1-21, in each first type mesa 17, both the source region 101 and the body region 102 are electrically connected to the first load terminal 11. At least the body region 102 isolates the source region 101 from the drift region 100.

In the IGBT-only region 1-21, each first type mesa 17 is arranged adjacent at least one of the first control trenches 14-21. There, each first control trench 14-21 is configured to induce, in response to receiving a corresponding configuration of the first control signal 13-21, a conductive channel in the adjacent first type mesa 17 for conduction of the forward load current. Such a conductive channel induction is generally known to the skilled person and accordingly not explained in further detail here.

In the RC IGBT region 1-22, each first type mesa 17 is arranged adjacent at least one of the second control trenches 14-22. There, each second control trench 14-22 is configured to induce, in response to receiving a corresponding configuration of the second control signal 13-22, a conductive channel in the adjacent first type mesa 17 for conduction of the forward load current. As indicated above, such a conductive channel induction is generally known to the skilled person and accordingly not explained in further detail here.

In the hybrid region 1-24, each first type mesa 17 is arranged adjacent at least one of the first control trenches 14-21 or adjacent at least one of the second control trenches 14-22. Here, it is noted that the number of second control trenches 14-22 present in the hybrid region 1-21 can be within the range of 20% to 60% of the number of first control trenches 14-21 present in the hybrid region 1-21. For example, in the hybrid region 1-24, the first control trenches 14-21 and the second control trenches 14-22 are arranged in an alternating manner with respect to a first lateral direction X. For example, between each pair of control trenches 14-21/14-22, there is arranged a number of (zero, one, or more than one) source trenches 16.

For example, at least in the IGBT-only region 1-21 and optionally in the hybrid region 1-24, the trench-mesa-pattern may further comprise second type mesas 18 that are not equipped with a source region 101 and that may or may not be electrically connected to the first load terminal 11. Further, additional trench types, such as floating trenches (whose trench electrodes are not electrically connected to a defined potential) or further control trenches may be provided.

For example, in the optionally provided diode-only region 1-23, only source trenches 16 but no control trenches are provided. These source trenches 16 may laterally confine diode mesas 19 in the diode-only region 1-23, wherein, there, the body region 102 is electrically connected to the first load terminal 11. The diode mesas 19 are laterally confined by the source trenches 16.

The trench-mesa-pattern illustrated in FIG. 3 is an example. In another embodiment, trench-mesa-pattern different therefrom may be provided.

Here, it shall be understood that the configurations of the front side 110 and the back side 120, i.e., the trench-mesa-pattern at the front side 110 and the back side emitter 108 at the back side 120, can be aligned with each other according to the separation of the active region 1-2 into the hybrid region 1-24, the RC IGBT region 1-22, the IGBT-only region 1-21 and the optional diode-only region 1-23.

That is, in an embodiment,
the above explained trench-mesa-configuration in IGBT-only region 1-21 laterally overlaps with the above explained configuration of the first section 108-21 of the back side emitter 108 in the IGBT-only region 1-21;
the above explained trench-mesa-configuration in RC IGBT region 1-22 laterally overlaps with the above explained configuration of the second section 108-22 of the back side emitter 108 in the RC IGBT region 1-22;
the above explained trench-mesa-configuration in diode-only region 1-23 laterally overlaps with the above explained configuration of the third section 108-23 of the back side emitter 108 in the diode-only region 1-23; and
the above explained trench-mesa-configuration in hybrid region 1-24 laterally overlaps with the above explained configuration of the fourth section 108-24 of the back side emitter 108 in the hybrid region 1-24.

According to a further embodiment, during a desaturation phase of the RC IGBT 1, the RC IGBT 1 exhibits a first saturation voltage between the first load terminal 11 and the second load terminal 12 if the first control signal 13-21 is set to a value corresponding to an OFF state, a second saturation voltage between the first load terminal 11 and the second load terminal 12 if the second control signal 13-22 is set to a value corresponding to an OFF state, wherein the second saturation voltage is lower than the first saturation voltage.

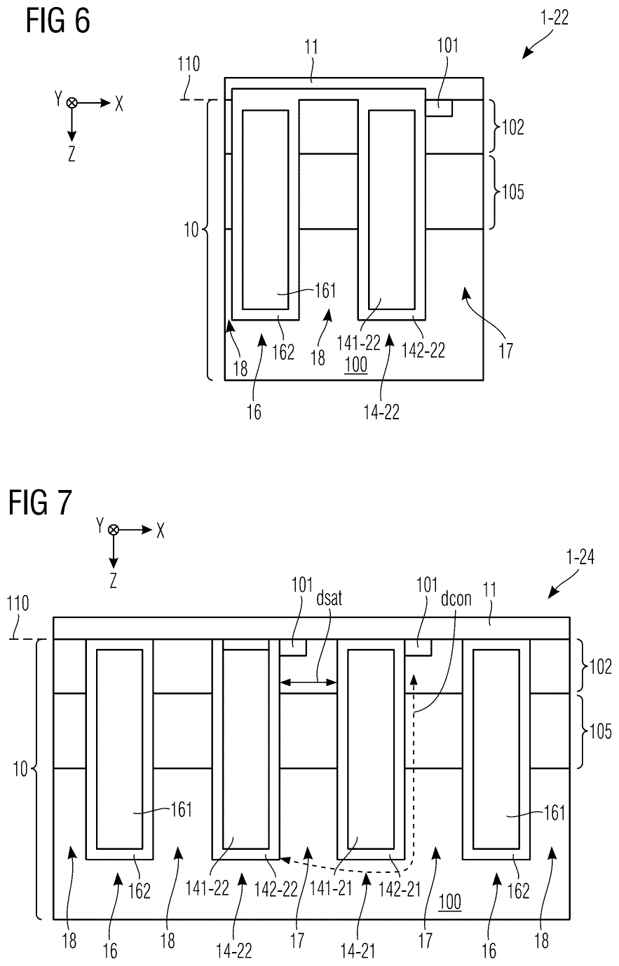

Further, e.g., in combination with the embodiment described in the preceding paragraph, the RC IGBT 1 may be provided with one or more of the following features:
I. In the hybrid region 1-24, the density of the first control trenches 14-21 may be greater than the density of the second control trenches 14-22. Thereby, a greater reduction of the carrier concentration may be achieved based on providing the first control signal 13-21 with an OFF-potential during a desaturation phase.
II. Only one of the first type mesas 17 is arranged adjacent to a respective one of the second control trenches 14-22 in the hybrid region 1-22, whereas each first control trench 14-21 may be laterally flanked by two of the first type mesas 17 (cf. FIG. 6). Thereby, the reduction of the carrier concentration based on providing the second control signal 13-22 with an OFF-potential is less as compared to providing the first control signal 13-21 with an OFF-potential.
III. A distance dsat-present during a desaturation phase-(cf. FIG. 7) between (i) a conductive channel adjacent to the second control trench 14-22 and (ii) the first control trench 14-21 is smaller than a distance dcon during a conduction phase between (i) a conductive channel adjacent to the first control trench 14-21 and (ii) the second control trench 14-22. This feature may be fulfilled even if there are arranged one or more other trenches.
IV. The channel width of the conductive channel adjacent to the second control trench 14-22 is smaller than the channel width of the conductive channel adjacent to the first control trench 14-21 and/or the channel width per area ratio (e.g., expressed in μm/mm²) associated with the conductive channel adjacent to the second control trench 14-22 is smaller than the channel width per area ratio (e.g., expressed in μm/mm²) associated with the conductive channel adjacent to the first control trench 14-21. Such configuration, which may for example be provided in the hybrid region 1-24, may lead to an improved charge carrier density for the conduction phase.
V. The channel width of the conductive channel adjacent to the second control trench 14-22 in the hybrid region 1-24 is smaller than the channel width of the conductive channel adjacent to the second control trench 14-22 in the RC IGBT region 1-22 and/or the channel width per area ratio (e.g., expressed in μm/mm²) associated with conductive channel adjacent to the second control trench 14-22 in the hybrid region 1-24 is smaller than the channel width per area ratio (e.g., expressed in μm/mm²) associated with the conductive channel adjacent to the second control trench 14-22 in the RC IGBT region 1-22. Such configuration may allow for homogenizing of the load current situation between the hybrid region 1-24 and the RC IGBT region 1-22 during the desaturation phase, at least in a certain range of the load current. Furthermore, within the single chip, the channel widths of the conductive channels adjacent to the second control trenches 14-22 may vary from each other.

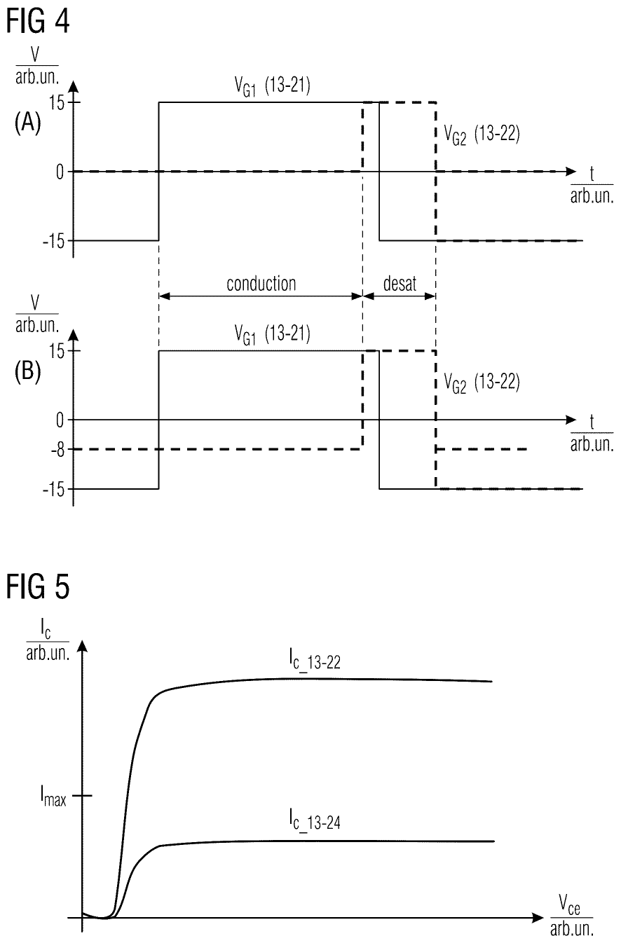

In an embodiment, the RC IGBT 1 further comprises a barrier region 105 of the first conductivity type that couples the trench-mesa-pattern in the IGBT-only region 1-21 and in the hybrid region 1-24 to the drift region 100. For example, the dopant concentration of the barrier region 105 is greater than the dopant concentration of the drift region 100. The dopant concentration or, respectively, the dopant dose of the barrier region 105 may be adjusted in accordance with the potentials the second control signal 13-22 may exhibit, which will be explained in more detail with respect to FIG. 4.

As illustrated in FIG. 3, the barrier region 105 is for example only provided in the IGBT-only region 1-21 and the hybrid region 1-24, but provided neither in the RC IGBT region 1-22 nor in the diode-only region 1-23.

Based on the above-described exemplary design, the IGBT-only region 1-21 may constitute a low saturation IGBT that is controlled based on the first control signal 13-21 (Gate 1), and the RC IGBT region 1-22 may constitute RCDC IGBT region with reverse conductivity (RC) and diode control (DC) characteristic that is controlled based on the second control signal 13-22 (Gate 2). The hybrid region 1-24 may constitute a combination of the low saturation IGBT and the RCDC IGBT and can accordingly be controlled based on both the first control signal 13-21 (Gate 1) and the second control signal 13-22 (Gate 2).

In an embodiment, the RC IGBT region 1-22 occupies a total of 10% to 30% of the active region 1-2, the IGBT-only region 1-21 occupies a total of 40% to 60% of the active region 1-2, the hybrid region 1-24 occupies a total of 5% to 20% of the active region 1-2 and the diode-only region 1-23 occupies a total of 0% to 15% of the active region 1-2. Additionally or alternatively, the RC IGBT region 1-22 occupies a volume amounting to at least 10% of the volume occupied by the IGBT-only region 1-21, and the hybrid region 1-24 occupies a volume amounting to at least 5% of the volume occupied by the IGBT-only region 1-21.

FIG. 6 illustrates a more detailed example of a section of the RC IGBT region 1-22. Accordingly, two second type mesas 18 are arranged adjacent to the source trench 16. The source trench 16 includes a source trench electrode 161 electrically connected to the first load terminal 11. The source trench electrode 161 is isolated from the semiconductor body 10 based on the source trench insulator 162. The second control trench 14-22 is arranged between one of the second type mesas 18 and one of the first type mesas 17. The second control trench 14-22 includes a second control trench electrode 141-22 configured to receive the second control signal 13-22 (Gate 2). The second control trench electrode 141-22 is isolated from the semiconductor body 10 based on the second control trench insulator 142-22. In the IGBT-only region 1-21, the setup is similar, except that in place of the second control trench 14-22 there is arranged a first control trench.

FIG. 7 illustrates a more detailed example of a section of the hybrid region 1-24. Also there, two second type mesas 18 or one of the second type mesas and one of the first type mesa 17 can be arranged adjacent to each source trench 16. The second control trench 14-22 is arranged between one of the second type mesas 18 and one of the first type mesas 17. The first control trench 14-21 is arranged between two of the first type mesas 17. As the second control trench 14-22, the first control trench 14-21 includes a first control trench electrode 141-21 configured to receive the first control signal 13-21 (Gate 1). The first control trench electrode 141-21 is isolated from the semiconductor body 10 based on the first control trench insulator 142-21. However, each conductive channel formed below a respective source region 101 is controlled by either the first control trench electrode 141-21 or the second control trench electrode 141-22, in accordance with an embodiment.

Due to their difference in configuration, the hybrid region 1-24 exhibits a theoretical standalone output characteristic that is different from a theoretical standalone output characteristic of the RC IGBT region 1-22. This aspect is exemplarily illustrated in FIG. 5. There, the horizontal axis indicates the voltage V_{CE} across the first load terminal 11 and the second load terminal 12. The vertical axis indicates the forward load current I_{C}. Both the first control signal 13-21 (Gate 1) and the second control signal 13-22 (Gate 2) exhibit a configuration corresponding to an ON state of the RC IGBT 1. In the hybrid region 1-24, the forward load current I_{C} is limited to a value below a maximum value Iₘₐₓ, whereas the RC IGBT region 1-22 is configured to conduct a forward load current I_{C} greater than the maximum value Iₘₐₓ. For example, as apparent from FIG. 3, the RC IGBT region 1-22 may exhibit a conductive-channel-width per area ratio that is (e.g., significantly) greater than the conductive-channel-width per area ratio in the hybrid region 1-24 (cf. the high density of the source regions 101 in the RC IGBT region 1-22 as compared to the hybrid region 1-24). The term theoretical standalone output characteristic describes an output curve of the respective region without interference with other regions.

Presented herein is also a method of operating an RC IGBT 1 according to one of the preceding embodiments. The method comprises controlling the RC IGBT 1 based on the first control signal 13-21 (Gate 1) and the second control signal 13-22 (Gate 2).

An exemplary method is illustrated in FIG. 4, to which it will now be referred. There, the first control signal 13-21 is illustrated with a continuous path denoted V_{G1} (i.e., voltage of the first control signal 13-21 (Gate 1)), and the second control signal 13-22 is illustrated with a dashed path denoted V_{G2}(i.e., voltage of the second control signal 13-22 (Gate 2)). Regarding the second control signal 13-22, two possibilities are explained for both variants (A) and (B) illustrated in FIG. 4, namely providing the second control signal 13-22 with two possible voltage levels or with three possible voltage levels. As usual, the first control signal 13-21 can be generated by providing a voltage between the first load terminal 11 and the first control trench electrodes 141-21, and the second control signal 13-22 can be generated by providing a voltage between the first load terminal 11 and the second control trench electrodes 141-22. In accordance with a third possibility which is not illustrated, the course of the first control signal 13-21 is identical to the courses illustrated in variants (A) and (B), and the course of the second control signal 13-22 corresponds to the courses illustrated in variants (A) and (B) with regards to timing, but the second control signal 13-22 exhibits the same OFF-potential as the first control signal 13-21, e.g., −15 V instead of 0V or −8V. That is, for the third possibility, the ON-potential and OFF-potential are the same for both control signals 13-21 and 13-22.

Regarding operation of the RC IGBT 1, it may be ensured, in an embodiment, that the carrier concentration in the hybrid region 1-24 during the conduction phase is not or at most slightly reduced due to the second control signal 13-22 being at an OFF-potential. At the same time, it may be ensured that based on the first control signal 13-21 being at an OFF-potential, the carrier concentration in the hybrid region 1-24 shall be significantly reduced during the desaturation phase.

In an example, it is hence provided that, at least during the desaturation phase of a forward conduction state of the RC IGBT 1, an OFF-potential of the second control signal 13-22 is different from an OFF-potential of the first control signal 13-21, e.g., greater than the OFF-potential of the first control signal 13-21, as illustrated in FIG. 4. For example, instead of −15 V, the OFF-potential of the second control signal 13-22 may be at −8V or a 0V.

Further, during the conduction phase, the OFF-potential of the second control signal 13-22 could be at 0V or at −15V, whereas the OFF-potential of the first control signal 13-21 is at −15V.

In case of a negative OFF-potential, it may be advantageous to provide the barrier region 105, e.g., with a comparatively high dopant dose of more than 2*10¹³ cm⁻², e.g., a dose of 5*10¹³ cm⁻². In case of such barrier region 105, the saturation voltage V_{CE, sat} only slightly increases for OFF-potentials of the second control signal 13-22 in the range of 0V to −8V, which accordingly yields a low reduction of the carrier concentration, whereas for an OFF-potential of −15V of the first control signal 13-21, a large desaturation effect is observed.

Generally, during the conduction phase of the RC IGBT 1, irrespective of whether the RC IGBT 1 conducts a forward or a reverse load current, the potential of the first control signal 13-21 may be greater as a first threshold value (e.g., at +15V), whereas the potential of the second control signal 13-22 is lower than the first threshold value (e.g., at 0V or −8V), cf. FIG. 4, both variants (A) and (B).

Further, during the desaturation phase of the RC IGBT 1, irrespective of whether the RC IGBT 1 conducts a forward or a reverse load current, the potential of the first control signal 13-21 may be lower as a second threshold value (e.g., at −15V), whereas the potential of the second control signal 13-22 is greater than the second threshold value (e.g., at +15V), cf. FIG. 4, both variants (A) and (B).

In the above, embodiments pertaining to RC IGBTs, and corresponding operating methods were explained. For example, these RC IGBTs are based on silicon (Si). Accordingly, a monocrystalline semiconductor region or layer, e.g., the semiconductor body and its regions/zones, e.g., regions etc. can be a monocrystalline Si-region or Si-layer. In other embodiments, polycrystalline or amorphous silicon may be employed.

It should, however, be understood that the semiconductor body and its regions/zones can be made of any semiconductor material suitable for manufacturing a semiconductor device. Examples of such materials include, without being limited thereto, elementary semiconductor materials such as silicon (Si) or germanium (Ge), group IV compound semiconductor materials such as silicon carbide (SiC) or silicon germanium (SiGe), binary, ternary or quaternary III-V semiconductor materials such as gallium nitride (GaN), gallium arsenide (GaAs), gallium phosphide (GaP), indium phosphide (InP), indium gallium phosphide (InGaPa), aluminum gallium nitride (AlGaN), aluminum indium nitride (AlInN), indium gallium nitride (InGaN), aluminum gallium indium nitride (AlGaInN) or indium gallium arsenide phosphide (InGaAsP), and binary or ternary II-VI semiconductor materials such as cadmium telluride (CdTe) and mercury cadmium telluride (HgCdTe) to name few. The aforementioned semiconductor materials are also referred to as “homojunction semiconductor materials”. When combining two different semiconductor materials a heterojunction semiconductor material is formed. Examples of heterojunction semiconductor materials include, without being limited thereto, aluminum gallium nitride (AlGaN)-aluminum gallium indium nitride (AlGaInN), indium gallium nitride (InGaN)-aluminum gallium indium nitride (AlGaInN), indium gallium nitride (InGaN)-gallium nitride (GaN), aluminum gallium nitride (AlGaN)-gallium nitride (GaN), indium gallium nitride (InGaN)-aluminum gallium nitride (AlGaN), silicon-silicon carbide (SixCl-x) and silicon-SiGe heterojunction semiconductor materials. For power semiconductor switches applications currently mainly Si, SiC, GaAs and GaN materials are used.

Spatially relative terms such as “under”, “below”, “lower”, “over”, “upper” and the like, are used for ease of description to explain the positioning of one element relative to a second element. These terms are intended to encompass different orientations of the respective device in addition to different orientations than those depicted in the figures. Further, terms such as “first”, “second”, and the like, are also used to describe various elements, regions, sections, etc. and are also not intended to be limiting. Like terms may refer to like elements throughout the description.

As used herein, the terms “having”, “containing”, “including”, “comprising”, “exhibiting” and the like are open ended terms that indicate the presence of stated elements or features, but do not preclude additional elements or features.

The expression “and/or” should be interpreted to cover all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

With the above range of variations and applications in mind, it should be understood that the present invention is not limited by the foregoing description, nor is it limited by the accompanying drawings. Instead, the present invention is limited only by the following claims and their legal equivalents.

What is claimed is:

1. An RC IGBT, comprising:
in a single chip, an active region configured to conduct both a forward load current and a reverse load current between a first load terminal at a front side of a semiconductor body of the RC IGBT and a second load terminal at a back side of the semiconductor body,
wherein the active region is separated into at least an IGBT-only region, an RC IGBT region, and a hybrid region,
wherein at least 90% of the IGBT-only region is configured to conduct, based on a first control signal, only the forward load current,
wherein at least 90% of the RC IGBT region is configured to conduct the reverse load current and, based on a second control signal, the forward load current,
wherein at least 90% of the hybrid region is configured to conduct, based on both the first control signal and the second control signal, the forward load current.

2. The RC IGBT of claim 1, wherein the second control signal is different from the first control signal.

3. The RC IGBT of claim 1, wherein the IGBT-only region, the RC IGBT region, and the hybrid region amount to at least 80% of the active region.

4. The RC IGBT of claim 1, wherein the IGBT-only region, the RC IGBT region, and the hybrid region are spatially separated from each other.

5. The RC IGBT of claim 4, wherein:
the IGBT-only region is a first contiguous region; and/or
the RC IGBT region is a second contiguous region; and/or
the hybrid region is a third contiguous region; and/or
one or more of the IGBT-only region, the RC IGBT region, and the hybrid region exhibit a total lateral extension of at least 60% of a vertical thickness of the semiconductor body.

6. The RC IGBT of claim 1, further comprising:
a diode-only region, at least 90% of which is configured to conduct only the reverse load current.

7. The RC IGBT of claim 6, wherein no control trench and/or no source region is present in the diode-only region.

8. The RC IGBT of claim 1, further comprising:
a drift region of a first conductivity type in the semiconductor body,
wherein the drift region is shared by each of the IGBT-only region, the RC IGBT region, and the hybrid region.

9. The RC IGBT of claim 8, further comprising:
a back side emitter in electrical connection with the second load terminal and coupled to the drift region,
wherein the back side emitter is configured in accordance with the separation of the active region into at least the IGBT-only region, the RC IGBT region, and the hybrid region.

10. The RC IGBT of claim 9, wherein the back side emitter comprises:
a first section of a second conductivity type in a portion of the active region where the IGBT-only region is present; and
a second section including both first subsections of a first conductivity type and second subsections of the second conductivity type in a portion of the active region where the RC IGBT region is present; and
a third section in a portion of the active region where the hybrid region is present and having a conductivity type configured in accordance with at least one of the first section and the second section.

11. The RC IGBT of claim 10, wherein the first section of the back side emitter:
exhibits, with respect to a total lateral extension of the first section along a first lateral direction and at a certain vertical level, an average dopant concentration of at least 2*10¹⁵ cm⁻³, and/or
is displaced from the RC IGBT region by at least the hybrid region; and/or
exhibits, at a certain vertical level and along at least one of the first lateral direction and a second lateral direction, a variation of the dopant concentration.

12. The RC IGBT of claim 10, wherein each of the first subsections of the second section of the back side emitter exhibits, with respect to a respective total lateral extension of each first subsection along the first lateral direction and at a certain vertical level, an average dopant concentration of at least 1*10¹⁸ cm⁻³.

13. The RC IGBT of claim 10, further comprising:
a field stop region the first conductivity type arranged in contact with both the drift region and with each of the first section, the second section, and the third section of the back side emitter,
wherein a dopant concentration of the field stop region is greater than a dopant concentration of the drift region.

14. The RC IGBT of claim 1, further comprising:
a trench-mesa-pattern at the front side of the semiconductor body,
wherein the trench-mesa-pattern is configured in accordance with the separation of the active region into at least the IGBT-only region, the RC IGBT region, and the hybrid region.

15. The RC IGBT of claim 14, wherein the trench-mesa-pattern comprises first control trenches configured to receive the first control signal and second control trenches configured to receive the second control signal, and wherein:
the IGBT-only region comprises a plurality of the first control trenches;
the RC IGBT region comprises a plurality of the second control trenches; and
the hybrid region comprises both a plurality of the first control trenches and a plurality of the second control trenches.

16. The RC IGBT of claim 14, wherein the trench-mesa-pattern further comprises:
source trenches electrically connected to the first load terminal and arranged at least in the IGBT-only region and the hybrid region.

17. The RC IGBT of claim 14, wherein the trench-mesa-pattern further comprises:
first type mesas arranged in each of the IGBT-only region, the RC IGBT region, and the hybrid region,
wherein each first type mesa includes a source region of the first conductivity type and a body region of the second conductivity type,
wherein both the source region and the body region are electrically connected to the first load terminal, and
wherein at least the body region isolates the source region from the drift region.

18. The RC IGBT of claim 17, wherein the trench-mesa-pattern further comprises first control trenches configured to receive the first control signal and second control trenches configured to receive the second control signal, and wherein:
the IGBT-only region comprises a plurality of the first control trenches;
the RC IGBT region comprises a plurality of the second control trenches; and
the hybrid region comprises both a plurality of the first control trenches and a plurality of the second control trenches.

19. The RC IGBT of claim 18, wherein:
in the IGBT-only region, each first type mesa is arranged adjacent at least one of the first control trenches and each first control trench is configured to induce, in response to receiving a corresponding configuration of the first control signal, a conductive channel in the adjacent first type mesa for conduction of the forward load current;
in the RC IGBT region, each first type mesa is arranged adjacent at least one of the second control trenches and each second control trench is configured to induce, in response to receiving a corresponding configuration of the second control signal, a conductive channel in the adjacent first type mesa for conduction of the forward load current; and
in the hybrid region, each first type mesa is arranged adjacent at least one of the first control trenches or adjacent at least one of the second control trenches.

20. The RC IGBT of claim 18, wherein in the hybrid region, the first control trenches and the second control trenches are arranged in an alternating manner with respect to a first lateral direction.

21. The RC IGBT of claim 14, further comprising:
a barrier region of the first conductivity type that couples the trench-mesa-pattern in the IGBT-only region and in the hybrid region to a drift region of a first conductivity type in the semiconductor body,
wherein the drift region is shared by each of the IGBT-only region, the RC IGBT region, and the hybrid region,
wherein a dopant concentration of the barrier region is greater than a dopant concentration of the drift region.

22. The RC IGBT of claim 1, wherein during a desaturation phase of the RC IGBT, the RC IGBT exhibits:
a first saturation voltage between the first load terminal and the second load terminal if the first control signal is set to a value corresponding to an OFF state; and
a second saturation voltage between the first load terminal and the second load terminal if the second control signal is set to a value corresponding to an OFF state, wherein the second saturation voltage is lower than the first saturation voltage.

23. The RC IGBT of claim 1, wherein the RC IGBT region exhibits a conductive-channel-width per area ratio greater than a conductive-channel-width per area ratio in the hybrid region.

24. A method of operating the RC IGBT of claim 1, the method comprising:
controlling the RC IGBT based on the first control signal and the second control signal.

25. The method of claim 24, wherein during a desaturation phase of a forward conduction state of the RC IGBT, an OFF-potential of the second control signal is different from an OFF-potential of the first control signal.
